(19) United States
(12) Patent Application Publication
(10) Pub. No.: US 2003/0197530 A1
(43) Pub. Date: Oct. 23, 2003

(54) Semiconductor logical operation circuit

(75) Inventor: Naoyuki Tamura, Kawasaki-Shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 10/170,438

(22) Filed: Jun. 14, 2002

(30) Foreign Application Priority Data
Apr. 18, 2002 (JP) 2002-116664

(51) Int. Cl. H03K 19/096

(52) U.S. Cl. 326/98

(57) ABSTRACT

A semiconductor logical operation circuit comprises a logical operation part to output a result of a predetermined logical operation with respect to a plurality of input signals to an output node; a precharger to precharge said output node at a constant-potential before an operation of said logical operation part; and a setting part to forcibly set said output node at a reference potential when said logical operation part is in a non-operation state.

### CROSS REFERENCE TO RELATED APPLICATION

This application is based upon and claims the benefit of priority from the prior Japanese Patent Application No. 2002-116664, filed on Apr. 18, 2002; the entire contents of which are incorporated herein by reference.

### BACKGROUND OF THE INVENTION

The present invention relates generally to a semiconductor logical operation circuit, and more particularly to a circuit suited for reducing a consumption of electric power.

A semiconductor integrated circuit is, with downsizing and a decrease in weight of devices using the semiconductor integrated circuit, highly required to reduce its electric power consumption. One of effective schemes of reducing the electric power consumption is to decrease the power consumption when the circuit is in a non-operation state.

For instance, one example of a conventional dynamic logical operation circuit is that a selection signal and a clock signal are ANDed. If a selection signal SEL assumes a high-level, a logical output node is set in a precharge state when a clock input CLK is at a low-level and set in an operation state when the clock input CLK is at a high-level, and, if the selection signal SEL assumes the low-level, the logical output node keeps its level high, i.e., the precharge state irrespective of the input of the logical operation circuit. This scheme reduces the power consumption by stopping a futile operation as on standby, i.e., during a non-operation.

This type of logical operation circuit often, however, involves the use of an N-channel MOS (NMOS) transistor, and a leak current is easy to flow even in an OFF-state in this type of transistor, and a quantity of this leak current can not be ignored especially when using a transistor of a submicron generation.

A method of raising a threshold value Vth of the transistor may be given as a method of reducing the leak current. In the case of a circuit taking this method, it follows that the threshold value Vth of the NMOS transistor increases, resulting in a problem of lowering an operation speed.

Furthermore, the leak current can be reduced also by downsizing the transistor, i.e., decreasing a gate width (W), however, there still exists a problem in which the operation speed is similarly decreased.

Moreover, a circuit using a CMOS transistor is often used as a circuit provided downstream of the output node, however, the size of the PMOS transistor is increased rather than downsizing in order to increase the operation speed thereof. In this case, however, a problem is that the leak current flows to the PMOS transistor having the large size when in the non-operation and the threshold value Vth can not be raised because of the PMOS transistor effecting the operation speed.

As explained above, the problem inherent in the conventional logical operation circuit is that it is difficult to reduce a consumption of electric power without decreasing the operation speed and that there is a large consumption of the electric power especially on standby state.

### SUMMARY OF THE INVENTION

According to one embodiment of the present invention, there is provided a semiconductor logical operation circuit comprising: a logical operation part to output a result of a predetermined logical operation with respect to a plurality of input signals to an output node; a precharger to precharge said output node at a constant-potential before an operation of said logical operation part; and a setting part to forcibly set said output node at a reference potential when said logical operation part is in a non-operation state.

According to another embodiment of the present invention, there is provided a semiconductor logical operation circuit comprising: a first logical operation unit including a first logical operation part to output a result of a first logical operation to a first output node with respect to a plurality of input signals, a first precharger to precharge said first output node at a high electric potential before an operation of said first logical operation part, and a first setting part forcibly pulling said first output node down to a ground potential when said first logical operation part is in a non-operation state; and a second logical operation unit including a second logical operation part to output a result of a second logical operation to a second output node with respect to the plurality of input signals, a second precharger to precharge said second output node at a high electric potential before an operation of said second logical operation part, and a second setting part forcibly pulling said second output node down to the ground potential when said second logical operation part is in the non-operation state.

### BRIEF DESCRIPTION OF THE DRAWINGS

FIG. 1 is a circuit diagram showing a first embodiment of the present invention;

FIG. 2 is a circuit diagram showing a modified example of the embodiment shown in FIG. 1; and

FIG. 3 is a circuit diagram showing a second embodiment of the present invention.

### DETAILED DESCRIPTION OF THE INVENTION

Embodiments of the present invention will hereinafter be described with reference to the accompanying drawings.

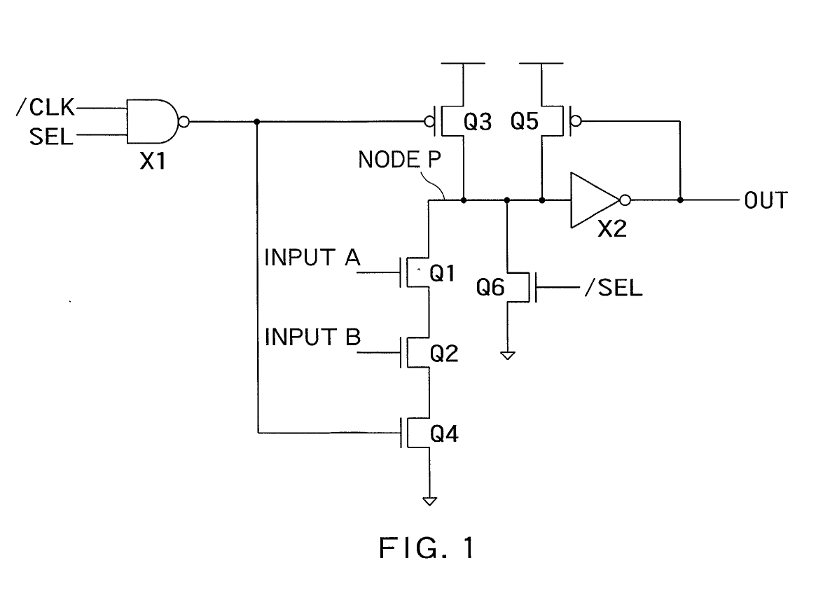

FIG. 1 is a diagram showing a circuit in a first embodiment of the present invention.

This circuit is defined as an AND circuit, wherein NMOS transistors Q1, Q2, of which gates receive an input A and an input B respectively, are connected in series, this AND circuit outputting a logical product thereof. The transistor Q1 is connected to a power supply via a PMOS transistor Q3 for precharge, which is connected in series to the transistor Q1. Further, the transistor Q2 is grounded via an NMOS transistor Q4 connected in series to the transistor Q2.

Gates of these transistors Q3, Q4 are each supplied with an output of a NAND gate X1 to which an invert signal /CLK (the symbol “/” represents an inversion) of a clock signal and a selection signal SEL are inputted. Note that the gate of the transistor Q3 is depicted as an inverted input terminal.

A connection node between the transistors Q1 and Q3 is a node P defined as a logical output node. An output from this node P is, though outputted via an inverter X2, given to a gate of a PMOS transistor Q5 provided between an input side of the inverter X2 and the power supply, thereby keeping the output with stability.

Furthermore, a transistor Q6, of which a gate receives an input of an invert selection signal /SEL, is connected between the node P and the ground.

Next, an operation of this circuit will be explained.

The discussion is at first focused on a case where the selection signal SEL assumes a high-level, i.e., a selecting state. In this case, when a clock input CLK is at a low-level, the transistor Q3 is in ON state, while the transistor Q4 is in OFF state. Therefore, the node P comes to a precharge state. When the clock input CLK is at the high-level, however, the transistor Q3 becomes OFF state and the transistor Q4 becomes ON state, the node P comes to an operating state. Further, the transistor Q6 remains OFF state at all times, and hence an inverted AND (NAND) signal of the input signals A, B is outputted in response to the high-level of the clock input CLK.

By contrast, when the selection signal SEL assumes the low-level, the transistor Q6 for discharge is always in ON state irrespective of how the inputs A, B are, and hence the node P is always pulled down to the ground potential and keeps the low-level as a discharge state.

In the case of adopting the circuit arrangement described above, when not operated, i.e., when the selection signal SEL is at the low-level, a leak current flows to the PMOS transistor such as the transistor for precharge and a transistor for keeping an output stability. The PMOS transistor does not, however, affect an operation speed. It is therefore possible to reduce the leak current when in operation without affecting the operation speed by downsizing these transistors to their minimums required or by raising a threshold value Vth.

Thus, according to this circuit, when the logical operation part does not execute the logical operation, the setting part forcibly sets the output node at the reference potential, whereby it is feasible to decrease both the current leak and the consumption of the electric power.

Moreover, in a CMOS circuit existing at downstream of the node P, the leak current flows to an NMOS transistor when in the non-operation. This NMOS transistor does not, however, affect the operation speed and is therefore downsized, and the leak current can be made smaller by increasing the threshold value Vth than in a case where the architecture of the present application is not adopted. Hence, the consumption of the electric power when in the non-operation can be restrained.

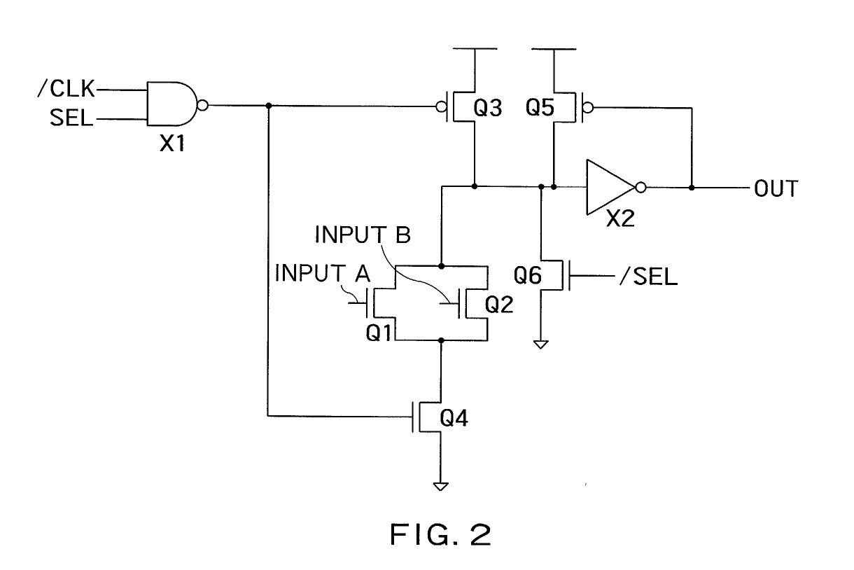

FIG. 2 shows a variation of the embodiment illustrated in FIG. 1. In this variation, two pieces of transistors Q1, Q2 connected in series in FIG. 1 are connected in parallel, whereby a logical addition (NOR) signal is obtained.

Other configurations and operations are absolutely the same as those shown in FIG. 1, and therefore the repetitive explanations are omitted.

According to this circuit arrangement, any types of logical operation circuits can be applied to the part for performing the logical operation. For example, the arrangement is not limited to what includes the two inputs as illustrated in the embodiment but may include three or more inputs. Further, a variety of logical operations other than OR and AND can be carried out.

Moreover, according to the present embodiment, the logical circuit part is basically constructed of the NMOS, wherein the precharge voltage is set to the power supply voltage, and the on-standby electric potential of the output node is set to the ground potential. The present invention is not, however, confined to this mode but may include such a mode that the operation occurs with an absolutely reverse logic. Namely, the logical circuit part is basically constructed of the PMOS, wherein the precharge voltage can be set to the ground potential, and the on-standby electric potential of the output node can be set to the power supply potential.

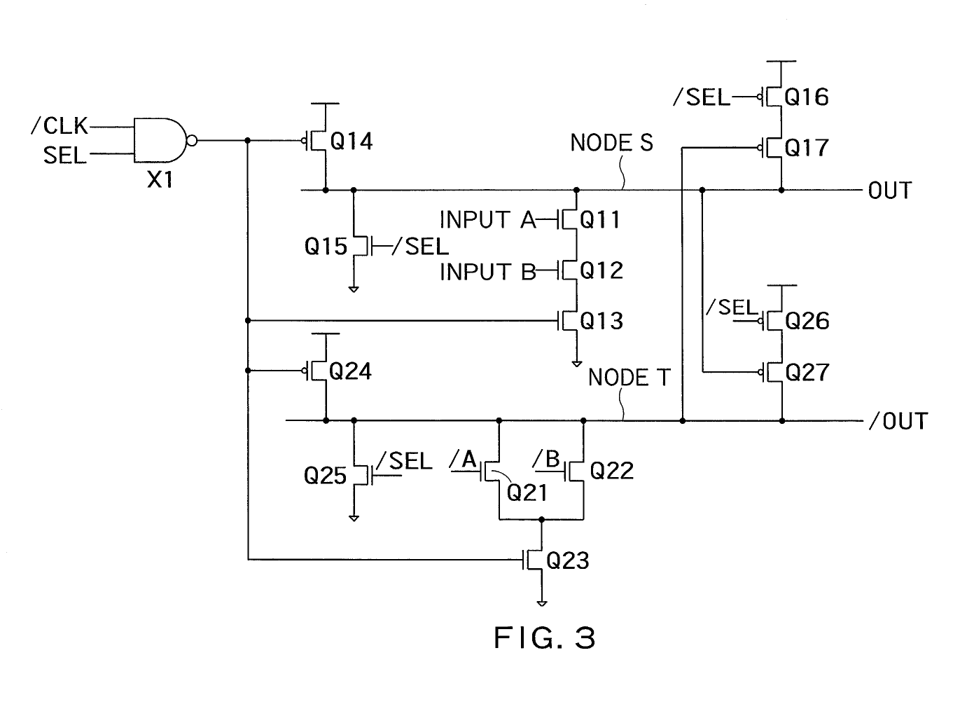

FIG. 3 is a circuit diagram showing a semiconductor logical operation circuit according to an another embodiment of the present invention.

The circuit in this embodiment is a so-called dual rail circuit capable of fetching an output from a different output terminal depending on a content of the input signal.

To begin with, the arrangement of this circuit will be described. A first output OUT is obtained based on such a configuration that a transistor Q11 of which a gate receives an input A, a transistor Q12 of which a gate receives an input B and a transistor Q13 of which a gate receives a clock signal, are connected in series between a node S and the ground. On the other hand, a second output /OUT is obtained based on such a configuration that a transistor Q21 of which a gate receives an input /A, a transistor Q22 of which a gate receives an input /B and a transistor Q23 of which a gate receives the clock signal, are connected in series between a node T and the ground.

Further, the clock signals are inputted respectively to PMOS transistors Q14, Q24 each controlled by the clock signals, and the nodes S and T are precharged through a conduction of these transistors. Moreover, NMOS transistors Q15, Q25 of which gates receives inputs of invert selection signals, are connected to those nodes. These transistors have functions of pulling the nodes S, T down to the ground potential when in the non-operation.

Further, a PMOS transistor Q16 of which a gate receives an input of an invert selection signal and a transistor Q17 to which the electric potential of the node T is inputted, are connected in series between the node S and the power supply. A PMOS transistor Q26 of which a gate receives an input of the invert selection signal and a transistor Q27 to which the electric potential of the node T is inputted, are connected in series between the node T and the power supply. This part schemes to charge, if an output occurs at any one of the two outputs nodes when in selection, the other node.

Note that FIG. 3 does not show the output part drawn as what is constructed of the inverter X2 and the transistor Q5 in FIGS. 1 and 2, however, an output part constructed the same or having a different construction can be provided.

According to this embodiment, the two logical operation outputs can be obtained in a way that reduces both the leak current and the consumption of the electric power as in the embodiment illustrated in FIGS. 1 and 2.

In this embodiment also, a variety of logical operation circuits to be used and multiple conductivity types of transistors can be used as in the first embodiment.

What is claimed is:

1. A semiconductor logical operation circuit comprising:
a logical operation part to output a result of a predetermined logical operation with respect to a plurality of input signals to an output node;
a precharger to precharge said output node at a constant-potential before an operation of said logical operation part; and
a setting part to forcibly set said output node at a reference potential when said logical operation part is in a non-operation state.

2. The semiconductor logical operation circuit according to claim 1, further comprising an output part to output a result of the logical operation in said output node of said logical operation part after the precharging operation.

3. The semiconductor logical operation circuit according to claim 2, where in said output part includes and inverter and an output stabilizing transistor controlled by an inverter and an output of said inverter and pulling up an electric potential on an input side of said inverter up to an electric potential of a power supply in accordance with an electric potential of said output node.

4. The semiconductor logical operation circuit according to claim 1, wherein said precharger receives a first control signal and is operable only when the first control signal indicates a selection, and
said setting part is operated when the first control signal indicates a non-selection.

5. The semiconductor logical operation circuit according to claim 4, wherein said precharger includes:
a gate section inputting the first control signal and a second control signal indicating an operation of outputting the result of the logical operation and outputting a precharge operation indicating signal when the first control signal indicates the selection and when the second control signal indicates the non-operation; and
a switch connecting said output node to a constant-potential power supply in accordance with the precharge operation indicating signal.

6. The semiconductor logical operation circuit according to claim 1, wherein said logical operation part is a NAND circuit.

7. The semiconductor logical operation circuit according to claim 1, wherein said logical operation part is a NOR circuit.

8. The semiconductor logical operation circuit according to claim 1, wherein said logical operation part is constructed of an NMOS transistor, the constant-potential is an electric potential of the power supply, and the reference potential is a ground potential.

9. The semiconductor logical operation circuit according to claim 1, wherein said logical operation part is constructed of the NMOS transistor, said precharger is constructed of a PMOS transistor, and a threshold value of the PMOS transistor is set higher than in a case where said setting par t does not exist.

10. The semiconductor logical operation circuit according to claim 3, wherein said logical operation part is constructed of the NMOS transistor, said precharger and the output stabilizing transistor are respectively constructed of PMOS transistors, and the threshold value of the PMOS transistor is set higher than in the case where said setting part does not exist.

11. A semiconductor logical operation circuit comprising:
a first logical operation unit including a first logical operation part to output a result of a first logical operation to a first output node with respect to a plurality of input signals, a first precharger to precharge said first output node at a high electric potential before an operation of said first logical operation part, and a first setting part forcibly pulling said first output node down to a ground potential when said first logical operation part is in a non-operation state; and
a second logical operation unit including a second logical operation part to output a result of a second logical operation to a second output node with respect to the plurality of input signals, a second precharger to precharge said second output node at a high electric potential before an operation of said second logical operation part, and a second setting part forcibly pulling said second output node down to the ground potential when said second logical operation part is in the non-operation state.

12. The semiconductor logical operation circuit according to claim 11, wherein said first and second logical operation parts are respectively constructed of NMOS transistors, said first and second prechargers are respectively constructed of PMOS transistors, and a threshold value of each of the PMOS transistors is set higher than in a case where said first and second setting parts do not exist.

13. The semiconductor logical operation circuit according to claim 11, further comprising first and second chargers to charge respectively output nodes on the other sides in accordance with an output of said first logical operation part and an output of said second logical operation part.

14. The semiconductor logical operation circuit according to claim 13, wherein said first and second logical operation parts are respectively constructed of NMOS transistors, said first and second prechargers and said first and second chargers are respectively constructed of PMOS transistors, and a threshold value of each of the PMOS transistors is set higher than in a case where said first and second setting parts do not exist.
